(19) United States
(12) Patent Application Publication
(10) Pub. No.: US 2010/0154877 A1
(43) Pub. Date: Jun. 24, 2010

(54) Semiconductor Core, Integrated Fibrous Photovoltaic Device

(76) Inventors: Venkata Adiseshaiah Bhagavatula, Big Flats, NY (US); David John McEnroe, Corning, NY (US)

Correspondence Address: CORNING INCORPORATED, SP-TI-3-1, CORNING, NY, 14831, US

(21) Appl. No.: 12/338,247

(22) Filed: Dec. 18, 2008

(51) Int. Cl. H01L 31/00; H01L 21/22

(52) U.S. Cl. 136/256; 136/261; 438/557; 438/545; 257/E21.135

(57) ABSTRACT

A cane having optical properties includes: a core formed of a semiconductor material; and a transparent cladding formed of glass, glass-ceramic, or polymer coaxially oriented about the core, the cane may be used to produce a photovoltaic device, including: a semiconductor core including at least one p-n junction, defined by respective n-type and p-type regions; a substantially transparent cladding in coaxial relationship with the semiconductor core, forming a longitudinally oriented cane; and first and second electrodes, each being electrically coupled to a respective one of the n-type and p-type regions.

### BACKGROUND

The present invention relates to methods and apparatus for providing an opto-electronic or a photovoltaic device, such as a device in which a semiconductor photo-sensitive core is integrated within a cladding layer or layers to produce an opto-electronic or a photovoltaic structure.

Photovoltaic solar cells are attractive mechanisms for generating electrical energy as they do not produce greenhouse gasses as a byproduct. Conventional superstrate or substrate photovoltaic devices include a flat substrate to which a flat semiconductor material is coupled. The semiconductor material (which may be crystalline silicon) includes a p-n junction, which has the characteristic of creating unbound charges (electrons and holes) and generating a voltage V across a pair of conductors when light passes through the junction.

The primary issues with conventional solar cell approaches are cost, efficiency, and form factor associated with fabrication of the solar cell. Various single crystal or thin film processes have been developed in an attempt to address these issues in the superstrate or substrate devices. Single crystal solar cells can have high efficiency, but the process is quite expensive. Thin film semiconductor fabrication techniques can be less expensive, but the energy conversion efficiency is normally quite low.

For the above reasons, and others, the cost of solar energy is about 2-3 times more expensive than conventional grid power. In some solar energy sectors, such as roof top applications in homes, apartment complexes, industrial parks or applications where grid power is not easily available, low weight and form factor may be a significant advantage. Accordingly, there is a need in the art for a new approach to providing photovoltaic solar cells, which enjoy characteristics of low cost, high efficiency, low weight and low form factor.

### SUMMARY

It is noted that the body of prior art associated with optical fiber fabrication and design has relevance to the context and discussion of one or more embodiments of the present invention. In this regard, there are differences in meaning between the structures and applications associated with an optical “fiber” and a “cane” structure. For example, an optical fiber is generally considered to be flexible, to have an outside diameter of about 125-500 um, and to be used primarily in optical communications applications. A cane structure, on the other hand, is somewhat stiffer than a fiber, has an outside diameter of about 1-5 mm, and may be used in solar energy conversion applications.

In accordance with one or more embodiments of the present invention, a cane having optical and/or opto-electronic properties includes: a core formed of a semiconductor material; and a transparent cladding formed of glass, glass-ceramic, or polymer coaxially oriented about the core.

The cane may be fabricated by: preparing a hollow blank suitable for use in a blank redraw process; introducing a semiconductor material into the hollow portion of the blank; heating the blank and semiconductor material in a redraw furnace such that the blank and the semiconductor material flow; and simultaneously drawing the blank and the semiconductor material such that a core of the semiconductor material is coaxially oriented within a cladding produced from the hollow blank, thereby forming a cane.

The above structures and techniques may be employed to produce a photovoltaic device, including: a semiconductor core including at least one p-n junction, defined by respective n-type and p-type regions; a substantially transparent cladding in coaxial relationship with the semiconductor core(s), forming a longitudinally oriented cane; and first and second electrodes, each being electrically coupled to a respective one of the n-type and p-type regions.

Other aspects, features, advantages, etc. will become apparent to one skilled in the art when the description of the invention herein is taken in conjunction with the accompanying drawings.

### BRIEF DESCRIPTION OF THE DRAWINGS

For the purposes of illustrating the various aspects of the invention, there are shown in the drawings forms that are presently preferred, it being understood, however, that the invention is not limited to the precise arrangements and instrumentalities shown.

FIG. 1A is a cross-sectional view of a semiconductor-core cane in accordance with one or more aspects of the present invention;

FIG. 1B is a cross-sectional schematic view of a photovoltaic device formed using the semiconductor-core cane of FIG. 1A in accordance with one or more aspects of the present invention;

FIG. 2 is a schematic view of a manufacturing device and process suitable for use in making the semiconductor-core cane of FIG. 1A;

FIG. 3 is a graph illustrating a diffraction pattern of a semiconductor-core cane sample of the kind illustrated in FIG. 1A;

FIG. 4 is a cross-sectional view of a multi-core cane in accordance with one or more aspects of the present invention;

FIG. 5 is a schematic view of a manufacturing device and process suitable for use in making the semiconductor-core cane of FIG. 4;

FIG. 6 is a cross-sectional view of a photovoltaic device formed using a semiconductor-core cane of the type illustrated in FIG. 1A and including an example of electrode connections in accordance with one or more aspects of the present invention;

FIGS. 7A, 7B are cross-sectional views of alternative photovoltaic devices formed using a semiconductor-core cane of the type illustrated in FIG. 1A and including a further examples of electrode connections in accordance with one or more aspects of the present invention;

FIGS. 8-9 are cross-sectional views of an alternative photovoltaic device formed using a transparent cane in accordance with one or more further aspects of the present invention;

FIGS. 10-11 are cross-sectional views of a further alternative photovoltaic device formed using a transparent cane in accordance with one or more further aspects of the present invention;

FIG. 12 is a cross-sectional view of a semiconductor-core cane including a central conductor in accordance with one or more aspects of the present invention;

FIG. 13 is a schematic view of a manufacturing device and process suitable for use in making the semiconductor-core cane of FIG. 6;

FIG. 14 is a cross-sectional view of a photovoltaic device formed using a semiconductor-core cane of the type illustrated in FIG. 13 and including an example of electrode connections in accordance with one or more aspects of the present invention;

FIG. 15A is a cross-sectional view of a semiconductor-core cane including a central tube for use in fabricating a conductor in accordance with one or more aspects of the present invention;

FIG. 15B is a cross-sectional view of the semiconductor-core cane of FIG. 15A with the central tube etched away leaving an aperture for accepting the conductor in accordance with one or more aspects of the present invention;

FIG. 16 is a schematic view of a manufacturing device and process suitable for use in making the semiconductor-core cane of FIGS. 15A-15B

FIG. 17 is a cross-sectional view of a photovoltaic device formed using a semiconductor-core cane of the type illustrated in FIGS. 15A-15B and including an example of electrode connections in accordance with one or more aspects of the present invention;

FIG. 18 is a cross-sectional view of a photovoltaic device/module formed using one or more semiconductor-core cane structures in accordance with one or more aspects of the present invention; and

FIG. 19 is a cross-sectional view of an alternative photovoltaic device/module formed using one or more semiconductor-core cane structures in accordance with one or more further aspects of the present invention.

### DETAILED DESCRIPTION

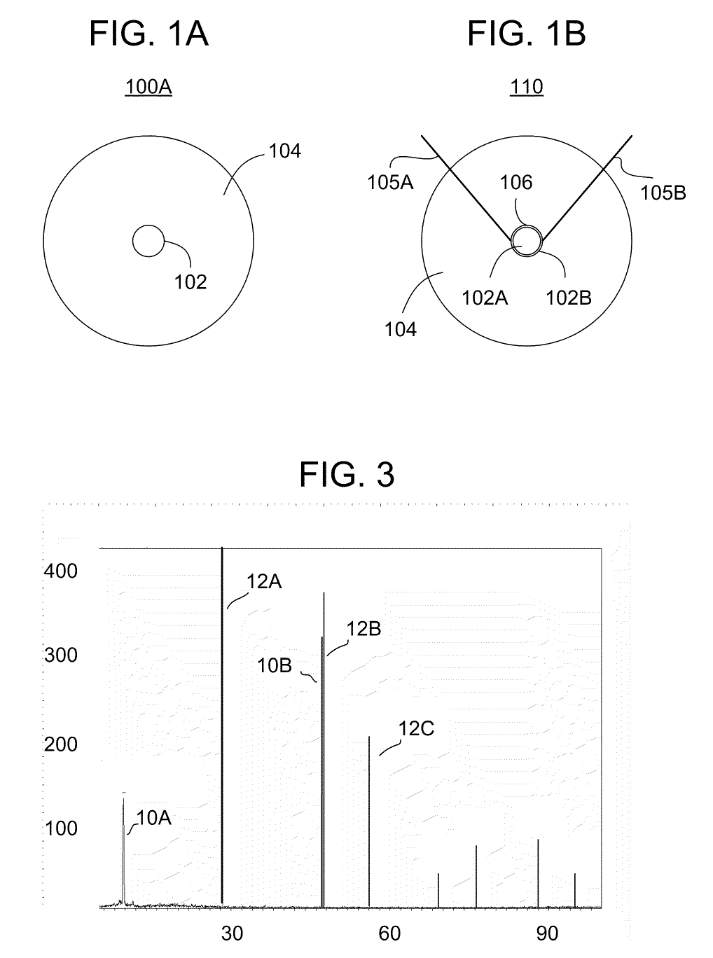

With reference to the drawings, wherein like numerals indicate like elements, there is shown in FIG. 1A a cross sectional view of a semiconductor-core cane (or simply cane) 100A in accordance with one or more aspects of the present invention. The cane 100A includes a central core 102 formed from a semiconductor material in co-axial relationship with a cladding or sheath 104. The sheath 104 is preferably transparent, such as a glass material, glass-ceramic, or polymer. As will be discussed in further detail later herein, the semiconductor core 102 and cladding 104 may be used in a variety of applications, such as in opto-electronic or photovoltaic devices for solar energy conversion.

In one or more embodiments herein, the semiconductor core 102 may be formed from an amorphous, a micro- or nano-crystalline, a polycrystalline, or a substantially single-crystal semiconductor material. The term “substantially” is used in describing the semiconductor core 102 to take account of the fact that semiconductor materials normally contain at least some internal or surface defects either inherently or purposely added, such as lattice defects or a few grain boundaries. The term substantially also reflects the fact that certain dopants may distort or otherwise affect the crystal structure of the semiconductor material. For the purposes of discussion, it may be assumed that the semiconductor core 102 is formed from silicon. The above features (and those described later herein) may be applied using other inorganic semiconductor materials such as the type III-V GaAs, copper indium gallium diselenide, InP, etc. Still other semiconductor materials may be employed, such as the IV-IV (i.e. SiGe, SiC), the elemental (i.e. Ge), or the II-VI (i.e. ZnO, ZnTe, etc.). Organic semiconductors can also be employed with proper consideration.

When the semiconductor core 102 and cladding 104 are used in a photovoltaic device, the semiconductor core 102 may be formed from materials selected to cover a broad range of wavelengths for efficient absorption of the solar energy spectrum. For example, single crystal semiconductor materials, poly-silicon, amorphous silicon, and/or other materials may be employed, with Si, Si—Ge, Ge, GaAs, etc. being some of the suitable materials. Additionally, crystal semiconductor materials may also be combined with polymer semiconductor materials. The solar energy absorption coefficient varies from a very large value to a small value as a function of solar wavelength, particularly near the band edge. For example, for single crystal silicon, the wavelength range of interest is from around 350 nm to about 1100 nm. The absorption coefficient for single crystal silicon at 400 nm is about 8.89E+04 cm−1. In contrast, the absorption coefficient for single crystal silicon at 900 nm is only 2.15E+02 cm−1.

The substantially transparent cladding 104 may be formed of glass, glass-ceramic, or polymer. In the case of the cladding 104 being formed from an oxide glass or an oxide glass-ceramic, suitable compositions include CORNING INCORPORATED GLASS COMPOSITION fused silica, Vycor™, other outside vapor deposition compositions, or other compositions that are melted from raw materials and formed by traditional techniques.

For reliability of operation over cycling thermal conditions, the cladding 104 may have a similar thermal coefficient of expansion as the semiconductor core 102. For example, the thermal expansion coefficients of the core 102 and the cladding 104 may be between about 2.0-3.0 ppm, such as 2.6 ppm (assuming that the semiconductor material of the core 102 is silicon).

For purposes of fabricating the cane 100A (which will be discussed later herein), it is desired that the material used to form the cladding 104, such as glass, have a softening point that is close to, but higher than, the melting point of the semiconductor core 102 material. For example, the material used to form the cladding 104 may have a softening point between about 100-300° C. above a melting point of the semiconductor material of the core 102. Assuming that the semiconductor material of the core 102 is single crystal silicon, the melting point of such material would be approximately 1410° C. Thus, a suitable composition for the cladding 104 may have a softening point of between about 1500-1700° C., such as about 1550-1600° C.

Taking into consideration both the thermal expansion issue and the fabrication issue, a suitably matched composition for the cladding 104 may have a softening point of around 1550-1600° C. and a thermal expansion coefficient around 2.6 ppm (again, assuming that the semiconductor material of the core 102 is single crystal silicon).

For a core 102 formed from silicon, a glass composition cladding 104 may be silica-based with one or more added dopants, such as boron, phosphorous, germanium, aluminum, titanium, fluorine, etc. The dopants may be used to modify the thermal expansion coefficients and the softening temperatures of the glass cladding 104. Alternatively or additionally, and as will be discussed later herein, the dopants may be used to provide a source of ions for diffusing into the semiconductor material of the core 102, in order to attain desirable electrical characteristics for certain applications, such as solar applications. An example of a composition suitable for forming a glass-based cladding 104 is a B2O3-GeO2-SiO2 glass with 5-25% B2O3 and 10-13% GeO2. Such glasses may be fabricated in the form of tubes or blanks using vapor deposition processes, or other well known techniques, and shaped or drawn to the required sizes.

Dimensionally, the cane 100A may be many meters long depending on the fabrication process used. The diameter of the core 102 may be between about 1-500 um, such as between about 50-500 um, such as about 100 um. In some embodiments discussed herein, the diameter of a single semiconductor core may be much smaller, such as between about 0.1-10 um, such as about 5 um. For opto-electronic fiber applications, especially with photonic bandgap fiber designs with multiple solid core and air regions, the feature sizes in the core may also be submicron. The diameter of the cladding 104 may be between about 1-10 mm; or between about 1-5 mm, such as between about 2-4 mm. Those skilled in the art will appreciate from the description herein that particular applications for the cane 100A may dictate the specific dimensions of the core 102 and cladding 104, some of which may be important. In the context of photovoltaic applications, the above dimensions of especially the core 102 may permit practically complete absorption of even long wavelength solar radiation, possibly without any need for multiple passages of the light rays through the core 102. This optical characteristic is advantageous for high photo-cell efficiency. The dimensions of the core 102 may also minimize the amount of semiconductor material used, thereby controlling manufacturing costs.

In some applications, such as the aforementioned photovoltaic applications, it may be advantageous to form the core 102 from a substantially single crystal semiconductor material, and maintain as near to a single crystal material as possible through and after the cane fabrication process. Preferably, there are substantially no grain boundaries within the core 102 in a radial direction of the cane 100A. Additionally or alternatively, there are preferably substantially no grain boundaries in the core 102 within a range of about 1 mm to about 10 cm in an axial direction (into and out of the illustrated page) of the cane 100A. Additionally or alternatively, there are preferably substantially no grain boundaries in the core 102 within a range of about 10 mm to about 1 cm in the axial direction of the cane, such as within a range of about 5 mm to about 15 mm in the axial direction.

The ability to achieve a long, relatively smaller diameter cane 100A with high axial and radial stresses may help in the formation of a long single crystal or polycrystalline core 102. The few grain boundaries (or absence thereof) along the radial direction of the core 102 over few mm to one or more cm of length along the axial direction may be very advantageous in terms of achieving a high solar conversion efficiency, especially if charge collecting electrodes are placed along the radial direction where there are very few or no grain boundaries to trap the charged particles (as will be discussed later herein).

It is noted that, although the core 102 and the cladding 104 are illustrated as being of circular cross-section, which is preferred, other cross-sections are permitted.

As will be explored further herein, a cladding 104 of the transparent variety may serve multiple advantageous functions. The cladding 104 may provide the support for the semiconductor core 102 and protects the core 102 from environmental effects. In photo-voltaic applications, the cladding 104 may act as a dopant source for the formation of the p-n junction during the manufacturing process. In photovoltaic applications with the canes illuminated transverse to the long axis of the canes, the transparent cladding with cylindrical shape can act as an integrated concentrator lens. This concentration allows a larger area of the solar radiation to be focused on a much smaller area of the semiconductor junction. This concentration can be optimized by locating the semiconductor core closer to the focal point of the cylindrical cladding lens.

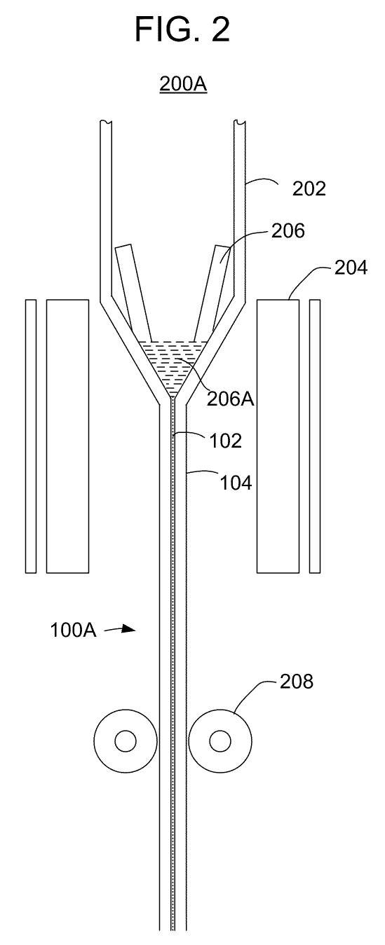

FIG. 2 is a schematic view of a redraw furnace 200A and process suitable for use in making the semiconductor-core cane 100A of FIG. 1A. In an initial phase of the process, a glass or glass ceramic preform (or blank) 202 is produced from which the cladding 104 and semiconductor core 102 are drawn from the furnace 200A.

For purposes of discussion, it may be assumed that the blank 202 is formed from glass or glass-ceramic. The blank 202 is advantageously hollow and suitable for use in a blank redraw process. The process by which the glass blank 202 is produced may be derived from known methods of manufacturing a soot optical fiber preform. The glass blank 202 may be formed by depositing silica-containing soot onto the outside of a rotating and translating mandrel or bait rod of glass. This process is known as the outside vapor deposition (OVD) process. (It is understood, however, that other techniques that employ melting raw materials and forming using traditional techniques may also be employed. The soot is formed by providing a glass precursor in gaseous form to the flame of a burner, thereby oxidizing the glass precursor. A fuel, such as methane (CH4), and a combustion supporting gas, such as oxygen, are provided to the burner and ignited to form the flame. Mass flow controllers meter the appropriate amounts of a suitable dopant compound, a silica glass precursor, fuel and combustion supporting gas to the burner. The soot perform may be consolidated in a consolidation furnace to form the hollow, consolidated blank 202. The blank 202 may also be shaped as needed by processes such as grinding to obtain the cross-sectional shapes needed. An alternative tube (202 blank) fabrication processes may involve the extrusion of a glass tube, core-drilling a glass/glass ceramic rod or forming a glass/glass ceramic by casting into a mold.

A semiconductor material 206 is introduced into the hollow portion of the blank 202. The semiconductor material 206 may be in the form of one or more of semiconductor rods, bars, plates, powders, pieces, and powders. The semiconductor material may also be deposited as thick layers using CVD, PECVD processes, or slurry casting. In order to control reasonable variations in the rates of draw and desirable dimension tolerances (as well as electrical and optical characteristics) semiconductor rods or bars may be preferred. The rods or bars of semiconductor material 206 are of suitable dimensions (length and diameter) and the dimension of the central hollow of the blank 202 are determined and controlled such that after redraw, the core 102 diameter is within the preferred range and tolerance.

The semiconductor material 206 may be formed from at least one of an amorphous, a micro- or nano-crystalline, a polycrystalline, a substantially single-crystal, and an organic semiconductor material, such as Si, GaAs, InP, SiGe, SiC, Ge, ZnO, and ZnTe.

The manufacturing process further includes heating the blank 202 and the semiconductor material 206 via heating elements 204 in the redraw furnace 200A such that the blank 202 and the semiconductor material 206 flow. The blank 202 should be purged of any oxygen or air to prevent any oxidation or reaction with the semiconductor material 206, which might degrade the desired properties of the core 102. Simultaneously, the blank 202 and the semiconductor material 206 are drawn out of the furnace 200A such that the core 102 of semiconductor material is coaxially oriented within the cladding 104.

The heating step may be such that a temperature of the blank 202 and the semiconductor material 206 is above a melting point of the semiconductor material 206 but below a melting point of the blank 202. By way of example, the temperature of the blank 202 and the semiconductor material 206 may be less than about 300° C. (such as between about 100-300° C.) above the melting point of the semiconductor material 206. For example, the when the semiconductor material 206 is silicon, the temperature of the blank 202 and the semiconductor material 206 may be between about 100-300° C. above about 1400° C. This puts the redraw temperature at between about 1500-1700° C.

The material used to form the blank 202 may also be controlled such that its thermal coefficient of expansion substantially matches that of the semiconductor material 206. For example, the coefficient of thermal expansion of the blank 202 may be established at between about 2.0-3.0 ppm (such as 2.6 ppm) in order to match the thermal expansion coefficient of silicon.

When the blank 202 is formed from a silica-based glass composition, one or more dopants may be added to the silica-based glass composition to modify at least one of the thermal expansion coefficient and softening temperatures thereof. The dopants include at least one of boron, phosphorous, germanium, aluminum, fluorine and titanium, etc.

For example, the silica-based glass composition may be a B2O3-GeO2-SiO2 composition, such as about 5-25% B2O3 and about 10-13% GeO2. As will be discussed later herein, the dopants may be added for other reasons related to the electrical properties of the semiconductor material of the core 102.

The above-discussed B2O3-GeO2-SiO2 composition may be well suited to form the glass blank 202, since the resultant softening point would be close to, but higher, than the melting point of a silicon semiconductor material used to form the core 102 (e.g., a redraw temperature of about 1650-1700° C.), and the resultant thermal expansion coefficient would be in the range of about 2.0-2.6 ppm.

At the above temperatures, the glass blank 202 softens and a tapered root section is formed at a base thereof. The semiconductor material 206 also melts and flows to the root section of the glass blank 202. The blank 202 and the semiconductor material 206 preferably form a “gob section,” from which the cane 100A is drawn, where the blank 202 is soft (but not molten) and the semiconductor material 206 is at least partially molten 206A.

It is preferred that care be taken so that the semiconductor material 206 (such as the rods or bars) are placed slightly above the initial gob section of the glass blank 202. This may assist in the formation of a smooth root section and also satisfactory core 102 formation. In other words, the introduction of the semiconductor material 206 into the hollow portion of the blank 202 includes positioning the non-molten section of the semiconductor material 206 away from the gob section in a direction opposite to the direction that the cane 100A is drawn. During the draw, the semiconductor material 206A close to the root section in the hot zone is molten and the un-melted semiconductor material 206 (particularly the rod formation) continuously feeds down and remains in contact with the molten semiconductor material 206A. While the invention is not bound by any theory of operation, it is believed that the above molten semiconductor material 206A, the continuous feeding of the non-molten material 206, and the draw of the glass blank 202 and semiconductor material 206 into a long, smaller diameter cane 100A lead to high axial and radial stresses, which may result in the formation of long single crystal or polycrystalline semiconductor structures within the core 102.

Using the fabrication process discussed herein, the original outer diameter of the blank 202, the inner diameter of the hollow thereof, the semiconductor material 206 (e.g., rod) diameter, and the final redraw diameter (among other variables of redraw) dictate the core 102 dimension and semiconductor usage rate. In this regard, in combination with heating, the blank 202 and the semiconductor material 206 are simultaneously drawn such that the core 102 of semiconductor material 206 is coaxially oriented within the cladding 104. A control system (not shown) varies the tension applied to the cane 100A by suitable control signals to a tension mechanism 208, shown as two tractor wheels, to draw down the cane 100A at the proper speed and tension. In this way, it is possible to derive a length of core cane 100A having a desired inner diameter for the core 102 and a desired outer diameter for the cladding 104. For example, as discussed above, in photovoltaic applications, there may be significant advantages to controlling the diameter of the core 102 of the cane 100A to between about 1-500 um, such as between about 50-500 um, such as about 100 um. In some other applications (such as multi-cane structures within a single cladding, which will be discussed later herein), smaller diameter cores 102 are desirable, such as between about 0.1-10 um, 3-8 um, such as about 5 um. In applications involving opto-electronic fiber devices with photonic band-gap designs, the feature sizes within the multiple segments in the core 102 may be smaller than a micron.

The cane 100A is cooled as it is drawn down below the furnace and measured for final diameter by a non-contact sensor. One or more coatings may be applied and cured using suitable coating apparatus and processes known in the art. The specific types of coatings that may be suitable depend on the application to which the cane 100A is directed. The cane 100A may be wound via by a feedhead onto a storage spool if the cane diameter is small enough, i.e., as a fiber may be wound on a spool. If the cane diameter is too large for such winding, the canes can be cut to the required lengths and stored. Usually cane diameters less than 150 microns may be spooled. While spooling cane diameters of up to 350 microns are possible, the spool diameter has to be increased.

The parameters of the above fabrication process are preferably adjusted and controlled to achieve further structural characteristics of the core 102 of the cane 100A. In particular, the semiconductor material 206 may be formed from substantially single crystal material and may be maintained as near to a single crystal material as possible through and after the cane 100A fabrication process as discussed above.

FIG. 3 is a graph illustrating a diffraction pattern of a semiconductor-core cane sample, similar to the kind of cane 100A illustrated in FIG. 1A. The vertical axis represents intensity in units of CPS, while the horizontal axis represents the two-theta values in units of degrees. The lines 10A, 10B indicate the x-ray diffraction intensity versus angle for the core material 102, while the lines 12A, 12B, 12C, etc. indicate the expected x-ray diffraction efficiency of randomly oriented semiconductor crystals, such as silicon crystals. The line 12B is the expected x-ray diffraction efficiency of single crystal silicon <220>. The data confirms that a cane, formed as discussed above with respect to cane 100A, has a high quality single crystal structure at the core 102, in this case a <220> orientation, despite the manufacturing process discussed above. Such high quality single crystal reformed/shaped semiconductor, e.g., silicon core cane 100A is desirable for use in an efficient solar cell application.

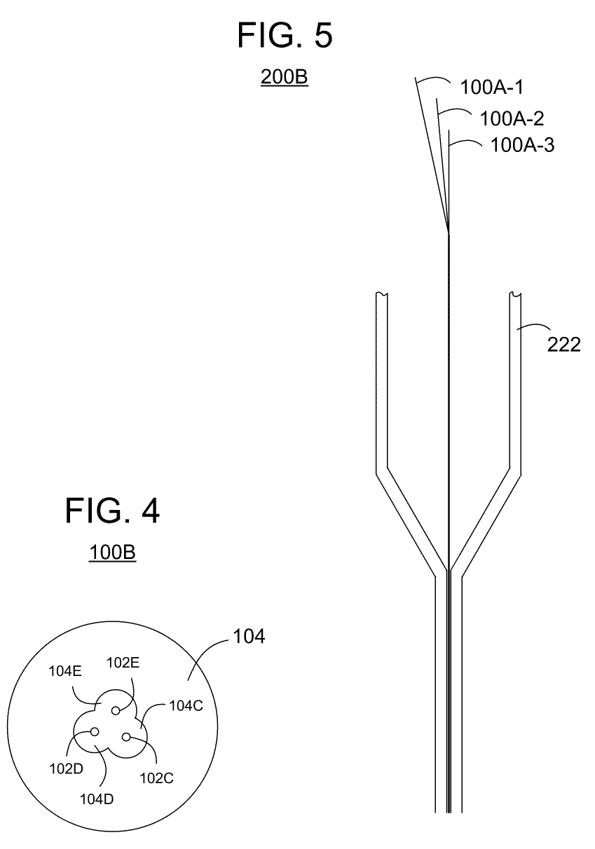

With reference to FIGS. 4-5, alternative embodiments of the present invention may include one or more multi-core canes 100B. The cane 100B includes a plurality of cores 102A, 102B, 102C, etc., formed of semiconductor material, and a transparent cladding 104 formed of glass, glass-ceramic, or polymer coaxially oriented about the cores 102. One or more diameters of the cores may be between about 1-10 um; between about 2-6 um; between about 3-8 um; and/or about 5 um. In applications involving opto-electronic fiber devices with photonic band-gap designs, the feature sizes within the multiple segments in the core may be smaller than a micron.

In some embodiments, the individual cores 102 may include a sub-cladding 104A, 104B, 104C, respectively. The process may include forming a plurality of separate canes 100A-1, 100A-2, 100A-3, etc., using the steps of preparing, introducing, heating and drawing discussed above with respect to FIG. 2 and the associated embodiments. The plurality of canes 100A-1, 100A-2, 100A-3 (plus or minus any reasonable number of such canes), once formed may be introducing into a hollow portion of a further blank 222. The further blank 222 and plurality of canes 100A-1 100A-2, 100A-3 are then heated in a redraw furnace such that the blank 222 and possibly the sub-cladding of the plurality of canes 100A-1 100A-2, 100A-3 flow. The blank 222 and the plurality of canes 100A-1 100A-2, 100A-3 are simultaneously drawn during the heating process such that a core 102 of the plurality of canes 100A-1 100A-2, 100A-3 is coaxially oriented within a further cladding 104 produced from the further hollow blank 222. The plurality of canes 100A-1 etc., may consist of semiconductor cores 102 of a same material type or different material types. Such blanks would lead to multi-junction PV devices with spatially separated p-n junctions. Additionally, they can also be optical fiber canes with optically transmitting materials for core and cladding. The canes 100A-1 can be designed and shaped such that there are well designed void spaces for photonic band-gap fiber designs. For example, the cane 100B may further include at least one longitudinally oriented void (not shown) disposed among at least one of the plurality of cores 102.

While it is possible to spool the canes 100A-1, 100A-2, 100A-3, etc., if the diameters thereof are small enough, the material is not always in the form of a fiber that can be spooled. Most often, the size of the multiple canes 100A-1, 100A-2, 100A-3 inserted in the tube are a few mm in diameter and cannot be spooled. When the diameters of the canes 100A-1, 100A-2, 100A-3 prevent spooling, the canes are inserted in the blank 222 after being prefabricated using the same draw process. These canes 100A-1, 100A-2, 100A-3 may be stacked inside the blank 222 and redrawn into the final structure 100B. An additional/alternative step may be to machine an outer diameter of the canes 100A-1, 100A-2, 100A-3 such that they fit into the outer blank 222.

Although the semiconductor-core cane 100A of FIG. 1A may be used in any number of applications, one of interest that will be further developed herein is a photovoltaic device (or solar cell). FIG. 1B is a cross-sectional schematic view of a photovoltaic device 110 that may be formed using the semiconductor-core cane 100A of the type illustrated in FIG. 1A. It is noted that some of the specific structures of the photovoltaic device 110 are schematic (as opposed to being a practical blue-print) for the purposes of introducing the device for discussion purposes.

The photovoltaic device 110 includes a substantially transparent cladding 104, such as a glass cladding in coaxial relationship with the semiconductor core 102, such as silicon. The core 102 is constructed such that at least one photo-sensitive p-n junction 106 exists therein. One side of the p-n junction 106 may be formed via an n-doped region 102A of the core 102, while the other side of the p-n junction 106 may be formed via a p-doped region 102B of the core 102. At least one electrode 105A, 105B provides an electrical connection to each of the respective sides of the p-n junction 106.

It is understood that the structural and electrical details of the photo-sensitive p-n junction 106 are relatively complex, but are very well known and understood in the art. In solar-cell technologies, p-n junctions are formed in semiconductor materials to convert solar radiation into electrical current. These p-n junctions separate the electron-hole pairs created by the absorption of radiation to generate useful electrical current for an external load. Depending on the semiconductor material and process used, various types of solar-cell designs have been developed in the art. Some are simple p-n junctions, while others are more complex and are optimized for higher efficiency. More complicated junctions include p-i-n junctions. In some cases, p+ and n+ layers are added to the p-n and/or p-i-n junctions for improved charge collection and electrode/solar cell fabrication. In this application, when a p-n junction is referred to, it may include any of the various junctions indicated above, others known from existing literature, and/or those developed hereafter.

It is noted that the cladding 104 of the photovoltaic device 110 exhibits a desirable light directing characteristic. Indeed, the curvate characteristic of the outside contour of the cladding 104 tends to improve the collection of light into the cladding 104 and toward the p-n junction 106 for conversion into electricity.

Among the methods that may be employed to produce the photovoltaic device 110, it is preferred to employ one or more modified versions of the redraw processes discussed above with respect to FIG. 2. In one approach, the p-n junction 106 may be formed as the cane 100A is being drawn, which may be considered an in-situ p-n junction formation. This approach uses a precursor material for the blank 202 that contains dopants, such as boron, phosphorous, germanium, aluminum, titanium, etc. The dopants may be used to provide a source of ions for diffusing from the blank 202 into the semiconductor material of the core 102 during the drawing process, in order to attain desirable electrical characteristics within the core 102, e.g., the formation of the p-n junction 106.

For example, for a p-n junction 106 formed within a silicon core 102, boron would be a suitable dopant for diffusing into the silicon core 102 and forming a p-type semiconductor region. On the other hand, phosphorous would be a suitable dopant for diffusing into the silicon core 102 and forming an n-type region. Placing the dopants within the precursor material, such as glass, of the blank 202 will produce the diffusion of the dopants into the core 102 during the cane drawing process. The high temperatures of the draw may lead to diffusion of the dopant into the semiconductor material (e.g., silicon) to form the p-n junction 106.

With reference to FIG. 2, the in-situ p-n junction formation process may include forming the hollow blank 202 from a material including at least one dopant operating to provide a source of dopant atoms for diffusing into another material, e.g., the semiconductor material of the core 102. Introducing the semiconductor material 206 into the hollow portion of the blank 202 and heating the blank 202 and semiconductor material 206 in the redraw furnace 200A such that the blank 202 and the semiconductor material 206 flow. The blank 202 and the semiconductor material 206 are then drawn such that: (i) the core 102 formed by the semiconductor material 206 is coaxially oriented within the cladding 104 formed by the blank 202, and (ii) atoms from the dopant diffuse into the semiconductor material of the core 102 and form the p-n junction 106.

An example of a composition suitable for forming a blank 202 with the desired dopants is: B2O3-GeO2-SiO2 glass with 5-25% B2O3 and 10-13% GeO2.

Such in-situ formation of the p-n junction 106 may be a very cost effective process. If fast, low cost redraw of the cane 100A could not be optimized to lead to such in-situ formation of the p-n junction 106, the canes 100A may be further heat treated in a furnace to lead to further dopant diffusion from the cladding 104 into the core 102 to optimize the p-n junction 106 characteristics. Such a batch process can be scaled to efficient manufacture by stacking a very large number of canes 100A in a suitable oven or furnace. The equipment for performing such a process would not need to be very expensive as the relatively thick (mm scale) glass cladding 104 around the semiconductor of the core 102 provides a natural protection against contamination, oxidation, etc. This allows the high purity of the p-n junction 106 to be maintained without the need for expensive controlled atmosphere, high purity equipment or controls.

In an alternative embodiment, the cane 100B of FIG. 4, having two or three, or more cores 102 may be employed to produce a photovoltaic device, similar to the device 110 of FIG. 1B, but with multiple cores 102. In such an embodiment, the cores 102 may be of a same semiconductor type, (e.g., silicon, germanium, etc.) or one or more of the cores 102 may be of a different semiconductor type.

In yet another embodiment, the core 100B of FIG. 4, having two or three, or more cores 102 may be employed to produce an opto-electronic fiber device. For example, in a two core configuration, one core may include a semiconductor core 102 and another core 102B may be of a transparent material having a refractive index such that the core 102B and cladding 104 form an optical fiber. Thus, for example, the lateral spacing between the cores 102A, 102B may be such that light travelling down the core 102B (especially if the configuration is a single mode fiber) interacts with the p-n junction of the core 102A. This technique may be used to form photonic band-gap designs and/or designs including air/voids.

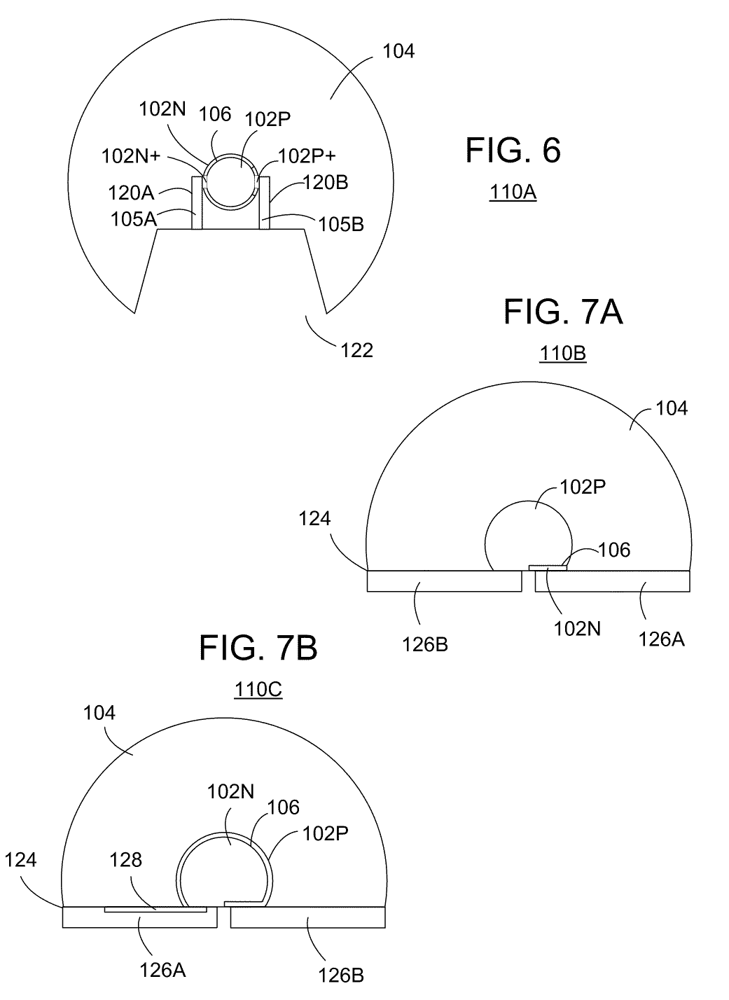

Using the techniques and structures discussed above, in addition to further disclosure and discussion herein, those skilled in the art will appreciate that there are many different solar applications which may be served by various aspects of the invention. With reference to FIG. 6, an example of a further photovoltaic device 110A is illustrated, which may be suitable, for example, for converting solar energy into electricity. FIG. 6 illustrates a cross-sectional schematic view of the photovoltaic device 110A, which may be formed using the semiconductor-core cane 100A of the type illustrated in FIG. 1A. Again, it is noted that some of the specific structures of the photovoltaic device 110A are schematic (as opposed to being a practical blue-print) for the purposes of introducing the device for discussion purposes.

The photovoltaic device 110A includes a substantially transparent cladding 104, such as a glass cladding in coaxial relationship with the semiconductor core 102, such as silicon. The core 102 includes at least one photo-sensitive p-n junction 106. In this example, the device 110A includes a p-type silicon core 102P formed from a p-type material. The p-n junction 106 is defined by a generally cylindrical region of n-type material 102N around the p-type material of the core 102. The n-type material 102N may be formed using the in-situ process discussed above with respect to FIG. 1B, or any other known or hereinafter developed process. For example, the p-type material of the core 102P may be established by placing a p-type semiconductor material in a hollow glass blank (where the blank includes a phosphorous dopant), and drawing a cane, like that of cane 100A. The phosphorous dopant may diffuse (during and/or after drawing) into the p-type silicon core 102 and form the n-type region 102N.

The photovoltaic device 110A may include a first channel 120A extending longitudinally along the cladding 104 such that at least a portion thereof is adjacent to and in communication with the n-type region 102N of the core 102. The photovoltaic device 110A may include a second channel 102B extending longitudinally along the cladding 104 such that at least a portion thereof is adjacent to and in communication with the p-type region 102P of the core 102. In one or more configurations, such as in the illustrated embodiment of FIG. 6, the device 110A includes at least one slot 122 on an exterior surface of the cladding 104. The slot 122 extends lengthwise in a longitudinal direction of the cladding 104 and extends radially toward but not through to the core 102. The slot 122 provides access to an interior region of the cladding 104 in order to prepare the channels 120A, 120B (as will be discussed further below).

Respective n+ and p+ portions, 102N+ and 102P+, are disposed at respective terminal ends of the first and second channels 120A, 120B in order to facilitate electrical connections to the respective n-type region 102N and p-type region 102P of the core 102. A first conductive material, such as conductive paste or epoxy, metallization, a wire, etc., may be disposed within the first channel 120A to form a first electrode 105A; and a second conductive material may be disposed within the second channel 120B to form a second electrode 105B. In one or more configurations, a wire may be maintained within the given channel 120 via a conductive epoxy. The channels 120A, 120B, n+ and p+ portions, 102N+ and 102P+, and the first and second electrodes 105A, 105B are located, sized and shaped such that voltage and current generated by the p-n junction 106 is accessible outside the cladding 104.

There are any number of fabrication processes that may be employed to produce the device 110A. In accordance with one of more aspects of the present invention, the device 110A may be fabricated by preparing a blank 202 from a material including at least one slot on an exterior surface thereof. The slot extends lengthwise in a longitudinal direction of the blank 202 and extends radially toward but not through to the hollow of the blank 202. The blank 202 and the semiconductor material 206 are drawn such that the slot 122 extends longitudinally along the cladding 104 and radially toward the core 102.

The first and second channels 120A, 120B may be formed via etching or laser ablation within the slot 122, such that the channels 102 extend longitudinally along the slot 122 of the cladding 104, and such that at least a portion of each is adjacent to and in communication with a respective one of the n-type and p-type regions 102N, 102P of the core 102. The etching may be achieved using ammonium bi-fluoride, HF acids, or any other suitable etchant. Using such acids, the etching process can be precisely controlled to make the channels 120. Laser ablation is also an attractive process for formation of the channels 120. In particular CO2 laser may be advantageous as it heats and ablates glass material, but is not absorbed by a silicon semiconductor material of the core 102. The characteristics may provide a self limiting channel formation and the ablation may stop once all the glass is ablated and the semiconductor is exposed for electrical contact formation.

The conductive material may then be introduced into the channels 120 in order to form the electrodes 105A, 105B. In one or more embodiments, a spin-on dopant or other similar liquid may be introduced into the channels 120A, 120B in order to form the n+ and p+ portions, 102N+ and 102P+. For example, the p+ portion 102P+ may be produced by introducing a spin-on dopant gel containing boron may be introduced into the channel 120B, which may come into contact with the p-type region 102P of the core 102. A heat treatment may then be applied to cause an excess of p-type ions to diffuse into the p-type region 102P, thus creating the p+ portion 102P+. The n+ portion 102N+ may be produced by introducing a spin-on dopant gel containing phosphorus may be introduced into the channel 120A, which may come into contact with the n-type region 102N of the core 102. A heat treatment may then be applied to cause an excess of n-type ions to diffuse into the n-type region 102N, thus creating the n+ portion 102N+.

Reference is now made to FIG. 7A, which is a cross-sectional view of an alternative photovoltaic device 110B formed using a semiconductor-core cane 100A of the type illustrated in FIG. 1A and including a further example of electrode connections in accordance with one or more aspects of the present invention. The photovoltaic device 110B includes a substantially transparent cladding 104, such as a glass cladding, in coaxial relationship with the semiconductor core 102, such as silicon. The core 102 includes at least one photo-sensitive p-n junction 106. In this example, the device 110B includes a p-type silicon core 102P formed from a p-type material. The p-n junction 106 is defined by a region of n-type material 102N located in communication with a periphery of the p-type material 102P of the core 102. The n-type material 102N may be formed using the in-situ process discussed above with respect to FIG. 1B, or any other known or hereinafter developed process. For example, the p-type material of the core 102P may be established by placing a p-type semiconductor material in a hollow glass blank (where the blank includes a phosphorous dopant), and drawing a cane, like that of cane 100A. The phosphorous dopant may diffuse (during and/or after drawing) into the p-type silicon core 102 and form the n-type region 102N.

In this example, the device 110B includes a substantially longitudinally oriented surface 124 (shown in cross-section) on which respective portions of the n-type region 102N and the p-type regions 102P of the core are exposed. The substantially longitudinally oriented surface 124 defines a substantially flat region characterizing the core 102 and cladding 104 in semi-circular cross-section. By way of example, the surface area of the semi-circular cross-section is greater than about 50% of a full circular cross section thereof. A first conductive layer 126A of material is disposed on the surface 124, is electrically coupled with the n-type region 102N, and forms a first electrode. A second conductive layer 126B of material is disposed on the surface 124 (adjacent to the layer 126A), is electrically coupled with the p-type region 102P and forms a second electrode. The layers 126A, 126B may be formed from conductive paste, epoxy, deposited metallization, etc., and may be deposited on the surface 124 using any of the known or hereinafter developed processes.

With reference to FIG. 7B, a cross-sectional view of a further alternative photovoltaic device 110C is illustrated. Again, the device 100C may be formed using a semiconductor-core cane 100A of the type illustrated in FIG. 1A. In this example, the device 110C exhibits some obviously similar characteristics as the device 110B of FIG. 7A, including that the core 102 has at least one photo-sensitive p-n junction 106. Among the differences, however, is that the central portion of the core 102 is formed of an n-type semiconductor material 102N, such as silicon. The p-n junction 106 is defined by a generally cylindrical region of p-type material 102P around the n-type material 102N of the core 102. The p-type material 102P may be formed using the in-situ process discussed above with respect to FIG. 1B, or any other known or hereinafter developed process. For example, the n-type material of the core 102N may be established by placing an n-type semiconductor material in a hollow glass blank (where the blank includes a boron dopant), and drawing a cane, like that of cane 100A. The boron dopant may diffuse (during and/or after drawing) into the n-type silicon core 102N and form the p-type region 102P.

In this example, the device 110C also includes a substantially longitudinally oriented surface 124 (shown in cross-section) on which respective portions of the n-type region 102N and the p-type regions 102P of the core 102 are exposed. A first conductive layer 126A of material is disposed on the surface 124, is electrically coupled with the n-type region 102N, and forms a first electrode. A layer of oxide 128, such as SiO2, prevents an electrical connection between the conductive material 126A and the p-type region 102P. A second conductive layer 126B of material is disposed on the surface 124 (adjacent to the layer 126A), is electrically coupled with the p-type region 102P and forms a second electrode.

Although there may be any number of ways to produce the longitudinally oriented surface 124, one considered desirable for purposes of one or more embodiments of the present invention is to polish the surface 124 into the cladding 104 to expose the respective portions of the n-type region 120N and the p-type region 120P of the core 102. Thereafter, the first and second conductive layers 126A, 126B may be disposed on the surface 124 such that they are electrically coupled with the respective n-type region 102N, and the p-type region 102N. The formation of the conductive layers 126A, 126B may be achieved, for example, via a vacuum deposition process.

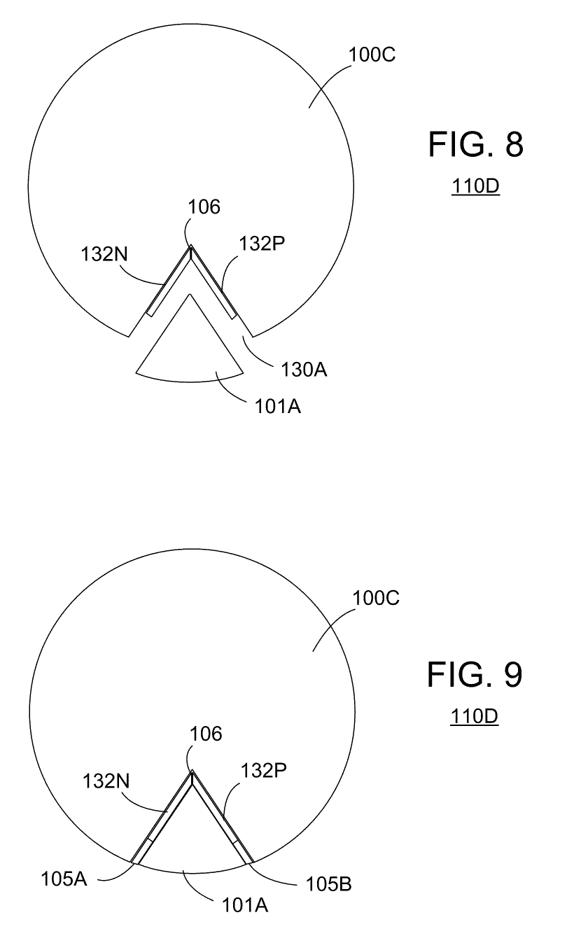

Reference is now made to FIGS. 8-11, which are cross-sectional views of alternative photovoltaic devices 110D, 110E formed using an alternative cane structure in accordance with one or more further aspects of the present invention.

The photovoltaic device 110D (FIGS. 8-9) includes a transparent cane 100C having an elongate length and circular cross-section. The cane 100C may be formed of glass, glass-ceramic, polymer, etc. The cane 100C includes at least one channel 130A extending longitudinally along the length thereof. In this example, the channel 130A has a substantially V-shaped cross-section. An n-type semiconductor plate 132N is disposed within the channel 130A, such as against one of the opposing surfaces of the channel 130A. A p-type semiconductor plate 132P is disposed within the channel 130A, such as against the opposite surface of the channel 130A. Respective peripheral edges of the n-type and p-type semiconductor plates 132N, 132P contact each other, and are in electrical communication with one another, to define at least one p-n junction 106. A plug 101A, which may be formed of the same material as the transparent cane 100C, fills a remainder of the channel 130A. First and second electrodes 105A, 105B, each being electrically coupled to a respective one of the n-type and p-type plates 132N, 132P, are disposed in respective voids. The channel 130A, the plates 132N, 132P, and the first and second electrodes 105A, 105B are located, sized and shaped such that voltage and current generated by the p-n junction 106 is accessible outside the cane 100C.

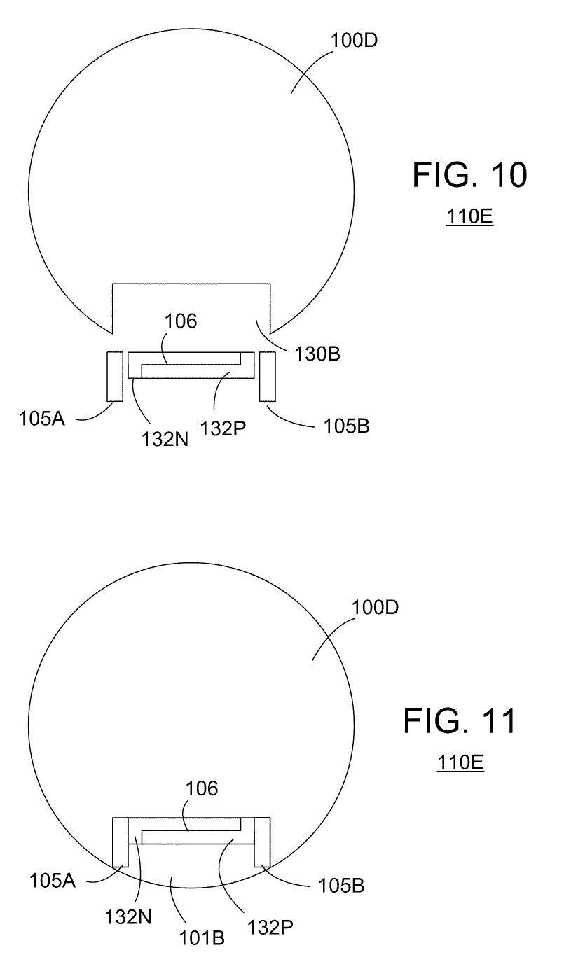

The photovoltaic device 110E (FIGS. 10-11) also includes a transparent cane 100D having an elongate length and circular cross-section. The cane 100D may be formed of glass, glass-ceramic, polymer, etc. The cane 100D includes at least one channel 130B extending longitudinally along the length thereof. In this example, the channel 130B has a substantially rectangular cross-section. An n-type semiconductor plate 132N is disposed within the channel 130B, such as against a bottom surface of the channel 130B. A p-type semiconductor plate 132P is disposed within the channel 130 in an overlapping orientation with respect to the plate 132N, such that respective major surfaces of the n-type and p-type semiconductor plates 132N, 132P contact each other to form the at least one p-n junction 106. It is noted that the plates 132N, 132P may be reversed in alternative embodiments. A plug 101B, which may be formed of the same material as the transparent cane 100D, fills a remainder of the channel 130B. First and second electrodes 105A, 105B, each being electrically coupled to a respective one of the n-type and p-type plates 132N, 132P, are disposed in respective voids. The channel 130B, the plates 132N, 132P, and the first and second electrodes 105A, 105B are located, sized and shaped such that voltage and current generated by the p-n junction 106 is accessible outside the cane 100D.

There may be any number of ways to manufacture the photovoltaic devices 110D, 110E of FIGS. 8-11. An exemplary process for such fabrication includes forming a channel extending longitudinally along a length of a blank of glass, glass-ceramic, or polymer. While the blank should be suitable for use in a blank redraw process, it need not be hollow. The channel may be V-shaped in order to produce the device 110D, it may be rectangular in order to produce the device 110E, or it may be any other suitable shape apparent to a skilled artisan given the disclosure herein.

The n-type and p-type semiconductor plates 132N, 132P may be disposed within the channel such that they are in electrical communication with one another, such as in one of the orientations illustrated in FIGS. 8-11, or any other orientation apparent to a skilled artisan given the disclosure herein. The plug 101 may be inserted into any remaining significant void of the channel (although it is not necessary that the void be completely filled).

The blank, the semiconductor plates 132N, 132P, and the plug 101 may then be heated in a redraw furnace, and simultaneously drawn such that the semiconductor plates 132N, 132P are disposed within the cane 100C and/or 100D in a generally circular cross-section. Thereafter, some of the material of the cane 100C and/or 100D may be removed (if necessary, e.g., via etching, laser ablation or polishing) to expose at least some portion of the semiconductor plates 132N, 132P. Respective electrode material, such as conductive paste, epoxy, wire, metallization, etc., may then be disposed within or on the cane 100C and/or 100D and in electrical communication with each of the semiconductor plates 132N, 132P such that voltage and current generated by the p-n junction 106 is accessible outside the cane 100C and/or 100D.

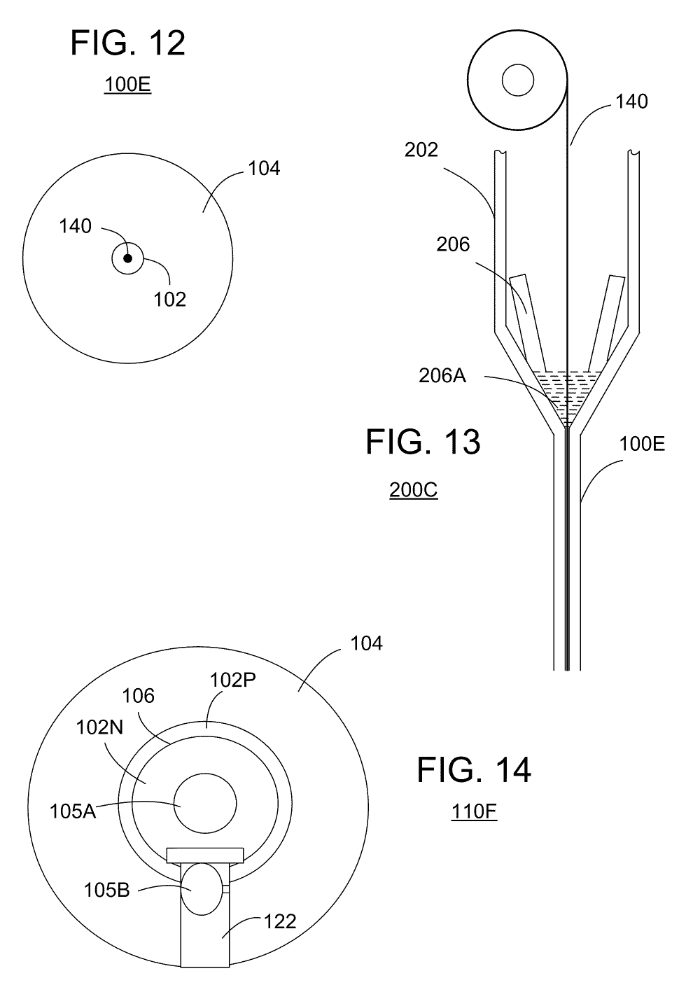

Reference is now made to FIGS. 12-13, FIG. 12 being a cross-sectional view of an alternative cane 100E in accordance with one or more further aspects of the present invention, and FIG. 13 being an illustration of a draw furnace 200C suitable for manufacturing the cane 100E. The cane 100E includes some of the structural elements of the cane 100A discussed above. For example, the cane 100E includes the central core 102 formed from a semiconductor material in co-axial relationship with a transparent cladding or sheath 104, such as a glass material, glass-ceramic, or polymer. In addition, the core 102 includes a conductor, such as a wire 140 coaxially oriented within the core 102. The wire may 140 be formed from high conductivity metals such as aluminum, copper or refractory metals like tungsten, molybdenum, etc.

The cane 100E may be used in any number of applications, although one example is the use in a photovoltaic application. In such an application, two electrodes are required to collect the charge generated at the p-n junction of the cell. From one or more embodiments above (such as is illustrated in FIG. 1B), one electrode is connected to the p-type material and the other electrode to the n-type material. In the cane 100E, the conductive wire 140 may serve as one of the electrodes, which is embedded inside the semiconductor core 102.

With reference to FIG. 13, in one embodiment, the process of fabricating the cane 100E may include manufacturing techniques using the steps of preparing, introducing, heating and drawing discussed above with respect to FIG. 2 and the associated embodiments. In addition, however, the conductive wire 140 is introduced into the hollow portion of the blank 202 with the semiconductor material 206. The blank 202, the semiconductor material 206, and the wire 140 are heated in the redraw furnace 200C such that the blank 202 and the semiconductor material 206 flow. The conductive wire 140 may be coated with a material prior to introducing same into the blank 202 for protecting the wire 104 during the heating and drawing process. Along with heating, the blank 202, the semiconductor material 206, and the wire 140 are simultaneously drawn such that the core 102 of the semiconductor material 206 is coaxially oriented within the cladding 104 produced from the hollow blank 202, and the wire 140 is coaxially oriented within the core 102, thereby forming the cane 100E.

The advantages of using conductive wire 140, such as a W (tungsten) or Al (aluminum) wire, is that such wires are highly conductive and provide little or no internal resistance, even in a meter-long cane-type solar cell. This may improve the charge collection and the solar cell efficiency. Also, such metal wires are relatively inexpensive as compared to using a vacuum deposition process to deposit metallization for the electrodes. Also, an advantage of such a co-drawn wire configuration is that the electrode formation step is combined with the semiconductor core formation, which approach is quite cost effective.

As will be appreciated by a skilled artisan from the disclosures herein, the cane 100E may be used to form a photovoltaic device (specific embodiments of which will be discussed later herein). In this regard, it may be desirable to produce an in-situ p-n junction 106 within the cane 100E during the heating and drawing process. This approach may be achieved by coating the conductive wire 140 with a dopant operating to provide a source of dopant atoms for diffusing into the semiconductor material of the core 102 during the heating and drawing process to form a p-n junction. For example, the dopant may include at least one of boron, phosphorous, germanium, aluminum, and titanium. For example, for a p-n junction formed within a silicon core 102, boron would be a suitable dopant for diffusing into the silicon core 102 and forming a p-type semiconductor region. On the other hand, phosphorous would be a suitable dopant for diffusing into the silicon core 102 and forming an n-type region. Placing the dopants on the wire 140 may produce diffusion of the dopants into the core 102 during the cane drawing process to form the p-n junction 106.

Reference is now made to FIG. 14, which is a cross-sectional view of an alternative photovoltaic device cane 110F in accordance with one or more further aspects of the present invention. The device 110F includes a central core 102 formed from a semiconductor material in co-axial relationship with a transparent cladding or sheath 104, such as a glass material, glass-ceramic, or polymer. The core 102 includes a conductive wire coaxially oriented within the core 102, which serves as a first electrode 105A. The core 102 includes at least one p-n junction 106, defined by respective n-type and p-type regions. In this example, the core 102 is formed from n-type material 102N and the conductive wire (electrode 105A) is disposed coaxially within, and in electrical contact with, the n-type material 120N of the core 102. A second electrode 105B is electrically coupled to the other of the n-type and p-type regions of the core 102, in this example the electrode 105B is connected to the p-type region 102P of the core 102. The p-type region 102P is a cylindrically-shaped portion at an outer most periphery of the core 102. In this embodiment, a slot 122 extends longitudinally along the cladding 104 and extends from an outer surface of the cladding 104 radially toward the core 102. The slot 122 may communicate with at least one of the n-type and p-type regions 102N, 102P of the core 102; in this example, the slot 122 communicates with the p-type region 102P. The second electrode 105B is disposed in the slot 122 and is electrically coupled to the p-type region 102N of the core 102.

There may be any number of ways to manufacture the photovoltaic device 110F. An exemplary process for such fabrication includes using some or all of the techniques discussed above with respect to forming the cane 100E (FIGS. 12-13) in order to obtain the first electrode 105A coaxially within the core 102. In addition, the dopant diffusing techniques discussed above with respect to forming the device 110A (FIG. 6) may be employed to obtain the cylindrically shaped n-type or p-type region 102N, 102P at the periphery of the core 102 (thereby forming the p-n junction). Some of the techniques discussed above with respect to forming the device 110A (FIG. 6) may be employed to obtain the slot 122 in the cladding 104. In addition, the slot 122 may be etched (or formed via laser ablation, etc.) such that it communicates with one of the n-type and p-type regions 102N, 102P (in this case the p-type region). Thereafter, a conductive material (e.g., paste, epoxy, metallization, etc.) may be disposed within the slot 122 to form the second electrode 105B.

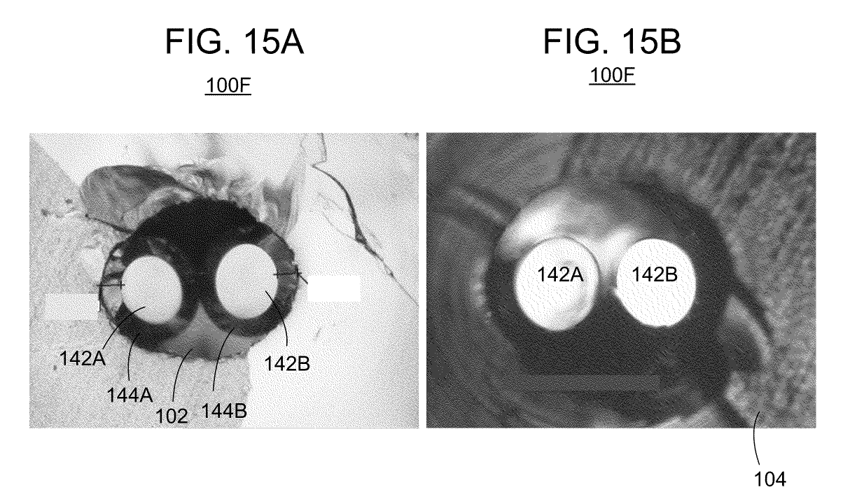

In some situations, depending on the heating and drawing temperatures of the fabrication process, the conductive wire 140 might not be able to withstand the high processing temperatures. In some cases, the heating of the wire 140 and/or diffusion of ions from the wire 140 may contaminate the semiconductor material of the core 102. As discussed above, a coating may be applied to the wire 140 to ameliorate these problems. Another approach, however, is to form the core 102 such that the conductive wire 140 may be “inserted” therein after the cane is drawn. This can be done at a room temperature, or a relatively low temperature process, and would not lead to some of the problems mentioned above. In this regard, reference is now made to FIGS. 15A-15B, which illustrate cross-sectional views of a cane 100F that includes at least one longitudinal aperture 142 through the core 102, suitable for inserting a wire 140 or conductive material after the drawing process has been completed. In this example, two apertures 142A, 142B are present, although any practical number of apertures 142 may be achieved according to various embodiments of the present invention.

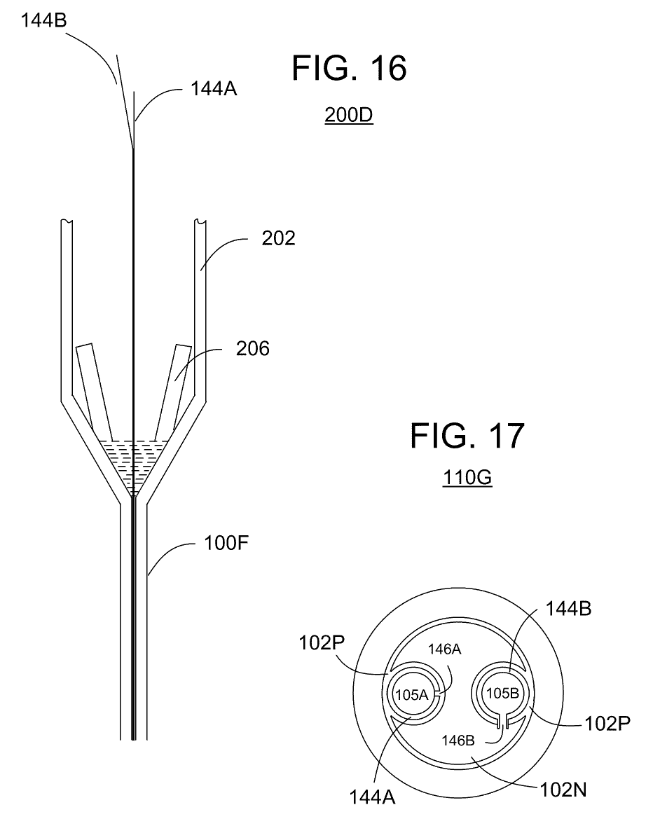

With reference to FIG. 16, the apertures 142A, 142B may be achieved using the steps of preparing, introducing, heating and drawing discussed above with respect to FIG. 2 and the associated embodiments. In addition, however, a pair of tubes (such as glass tubes) 144A, 144B may be introduced into the hollow portion of the blank 202 with the semiconductor material 206. The blank 202, the semiconductor material 206, and the tubes 144A, 144B are heated in the redraw furnace 200D such that the blank 202 and the semiconductor material 206 flow. Along with heating, the blank 202, the semiconductor material 206, and the tubes 144A, 144B are simultaneously drawn such that the core 102 of the semiconductor material 206 is coaxially oriented within the cladding 104 produced from the hollow blank 202, and tubes 144A, 144B are coaxially oriented within the core 102, thereby forming the cane 100F. As an example, the tubes 144A, 144B may be formed from a vycor composition, such as B2O3-SiO2.

Using similar techniques as those discussed above with respect to forming p-n junctions 106 for photovoltaic applications, the one or more tubes 144A, 144B may be coating with, or formed from, a dopant operating to provide a source of dopant atoms for diffusing into the semiconductor material of the core 102 during the heating and drawing process. Again, the dopant may include one or more of boron, phosphorous, germanium, aluminum, titanium, etc.

An etching process may be used to remove the glass material of the tubes 144A, 144B and leave only the apertures 142A, 142B (which would be slightly larger in diameter) as shown in FIG. 15B. Thereafter, a wire 140 or conductive epoxy may be introduced into the apertures 142A, 142B, notably at a lower processing temperature than the drawing process.

Reference is now made to FIG. 17, which is a cross-sectional view of an alternative photovoltaic device 110G in accordance with one or more further aspects of the present invention. In this embodiment, the tubes 144A, 144B discussed above with respect to FIG. 15A are not removed as part of the process of fabricating the photovoltaic device 110G, which may be advantageous because the etching process may be reduced. The photovoltaic device 110G includes a central core 102 formed from a semiconductor material in co-axial relationship with a transparent cladding or sheath 104, such as a glass material, glass-ceramic, or polymer. The semiconductor core 102 includes at least one p-n junction 106, defined by respective n-type and p-type regions 102N, 102P. Although the illustrated example has the n-type region 102N in the central area and the p-type region 102P at the periphery, those skilled in the art will appreciate that the arrangement may be reversed. The p-type region 102P is a cylindrically-shaped portion at an outer most periphery of the core 102.

A first conductor is disposed coaxially within the core 102 and serves as a first electrode 105A coupled to one of the n-type and p-type regions, in this example the p-type region 102P. A second conductor is disposed coaxially within the core 102 and serves as a second electrode 105B coupled to the other of the n-type and p-type regions, in this case the n-type region 102N. First and second tubes 144A, 144B, each surround a respective one of the first and second conductors 105A, 105B. The p-type region 102P of the cylindrically-shaped portion surrounds the first and second tubes 144A, 144B. Each of the tubes 144A, 144B includes respective longitudinally extending slots 146A, 146B, which extend through respective walls of the tubes 144A, 144B such that the first and second conductors are in electrical communication with the respective n-type and p-type regions 102N, 102P of the core 102.

As indicated previously, the cane drawing process can be repeated multiple times to obtain secondary canes. In this process the first set of canes can be obtained with cores of different semiconductor materials such as Si, Ge or a combination of Si and Ge in separate draw runs. The shape of the first set of canes can also be varied by shaping the cladding blank. The canes from these draw runs can be inserted in a second cladding blank to draw the second set of canes. This multiple draw process provides a number of advantages in the core segment materials and their composition and shape. For example, the core segments may include various p-n junctions of the same semiconductor type, or different semiconductor types. Further, the core segments may include a combination of semiconductor and optically transparent core and air/vacuum segments. Such processes may be suitable to make optoelectronic fibers and canes incorporating well known photonic band-gap fiber designs also. With such flexibility in the formation of the blank, various sized and shaped tubes and rods of different materials can be assembled for redraw. For example, with such structures and materials, it is possible to have p-n junctions in silicon material and also si-Ge material in the same blank. In addition to layering them, it is possible to have spatially separated p-n junctions, with Silicon p-n junction in one part of the core and si-Ge or Ge p-n junction in another part. Thus, various cross-sectional shapes and redraw process features permit not only multi-junction cells, but also spatially separated multi-junction cells for optimum solar collection.

An exemplary process for fabricating the photovoltaic device 110G includes using some or all of the techniques discussed above with respect to forming the cane 100F (FIGS. 15A, 16) in order to obtain the first and second tubes 144A, 144B and the conductors 105A, 105B coaxially within the core 102. In addition, the dopant diffusing techniques discussed above with respect to forming the device 110A (FIG. 6), and the dopant diffusing technique discussed above with respect to using dopant on the tubes 144A, 144B, may be employed to obtain the cylindrically shaped n-type or p-type region 102N, 102P at the periphery of the core 102 and surrounding the tubes 144A, 144B (thereby forming the p-n junction 106). It is noted, however, that the tubes 144A, 144B of this embodiment include respective longitudinally extending grooves. According to one embodiment, prior to the heating/drawing process, each groove may extend radially from an outer surface of the tube 144 toward the center, but not all the way through the wall of the tube 144. The grooved tubes 144A, 144B are drawn into the core 102 as discussed above with respect to FIGS. 15A, 16. Thereafter, the tubes 142 may be etched to extend the grooves all the way through the walls of the tubes so that the grooves communicate with the respective n-type and p-type regions 102N, 102P. Thereafter, a wire 140 or conductive epoxy may be introduced into the apertures 142A, 142B of the tubes 144A, 144B to form the electrodes 105A, 105B, which are then in electrical communication with the n-type and p-type regions 102N, 102P of the core 102.

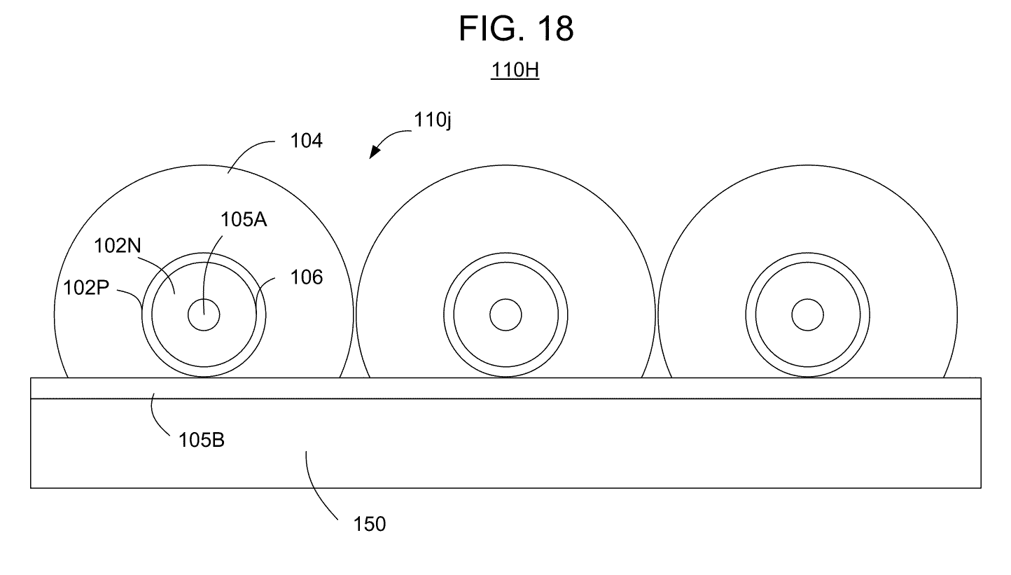

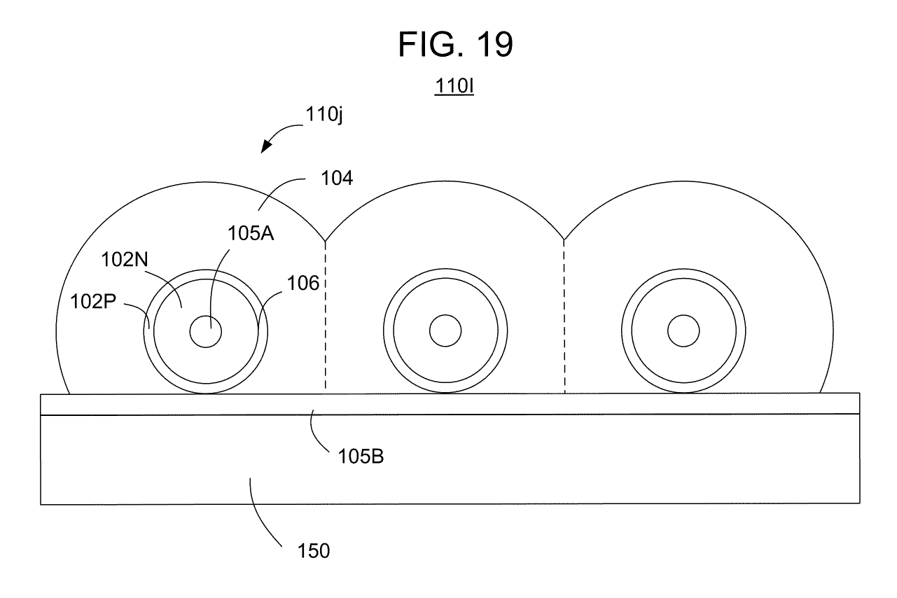

Reference is now made to FIGS. 18-19, which illustrate side, cross-sectional views of photovoltaic devices/modules 110H, 110I in accordance with one or more further aspects of the present invention. The photovoltaic device 110H of FIG. 18 includes a support structure 150 and a plurality of photovoltaic cells 110j coupled to the support structure 150. Each cell 110j is of substantially longitudinal extension and at least semi-circular cross-section. One or all of the cells 110j may include one or more of the structural, solar, photovoltaic, and/or electrical features discussed above with respect to any or all of the disclosed embodiments. The illustrated embodiment of the device 110H shows that the p-n junction 106 is formed of a cylindrically shaped region of p-type material 102P surrounding the core 102 of n-type material 102N (which has been discussed numerous times above). A first of the electrodes 105A of each cell is generally centrally located within the core 102 in coaxial relationship therewith. The second electrode 105B is shared among all of the cells 110j (although those skilled in the art will appreciate that the second electrode 105B could readily be separated for independent use by the respective cells 110j). The cladding 104 of the cells 110j has been removed, at least in the area of the second electrode 105B, such that the p-type region 102P of each cell 110j may be in electrical communication with the electrode 105B. Respective ones of the first and second electrodes 105A, 105B of the photovoltaic cells 110j are electrically coupled together to achieve an integrated source of voltage and current.

In this example of the photovoltaic device 110H, the plurality of photovoltaic cells 110j are disposed one next to the other such that the cladding 104 of a given one of the cells 110j is in close proximity, or touching, the cladding 104 of an adjacent one of the cells 110j. It is noted that all of the photovoltaic devices discussed above that include the cladding 104 exhibit a desirable light directing characteristic. Indeed, the curvate characteristic of the outside contour of the cladding 104 tends to improve the collection of light into the cladding 104 and toward the p-n junction 106 for conversion into electricity. In FIG. 19, the lateral cladding 104 of adjacent cells 110j of the photovoltaic device 110I has been removed such that a convex edge of the cladding 104 will tend to improve the collection of light into the cladding and to the p-n junctions 106 of the cells 110j.

The long axes of the cylindrical shaped devices 110j may be oriented the East-West direction so that the long length of the devices 110j allows the capture of the solar radiation as the sun moves over the horizon during the day. For low concentration designs, the high NA of the cladding 104 may capture the radiation without significant efficiency reduction even if the illumination is not on axis during the seasonal changes of sun's position on the horizon.

In addition to the embodiments discussed herein, additional optical mechanisms may be employed to enhance the absorption of solar energy and electrical power generation. For example, one or more lenses, prisms, reflectors, scattering surfaces, etc. that redirect the solar radiation for improved collection of light energy within the cladding 104 and toward the core 102.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

1. A photovoltaic device, comprising:
a semiconductor core including at least one p-n junction, defined by respective n-type and p-type regions;
a substantially transparent cladding in coaxial relationship with the semiconductor core, forming a longitudinally oriented cane; and
first and second electrodes, each being electrically coupled to a respective one of the n-type and p-type regions.

2. The photovoltaic device of claim 1, wherein the substantially transparent cladding operates to focus solar rays toward the at least one p-n junction.

3. The photovoltaic device of claim 1, further comprising:
at least one channel extending longitudinally along the cladding such that at least a portion thereof is adjacent to and in communication with at least one of the n-type and p-type regions of the core; and
a conductive material disposed within the at least one channel and forming at least one of the first and second electrodes,
wherein the at least one channel and at least one of the first and second electrodes are located, sized and shaped such that voltage and current generated by the p-n junction is accessible outside the cladding.

4. The photovoltaic device of claim 3, further comprising:
a first channel extending longitudinally along the cladding such that at least a portion thereof is adjacent to and in communication with the n-type region of the core;
a second channel extending longitudinally along the cladding such that at least a portion thereof is adjacent to and in communication with the p-type region of the core;
a first conductive material disposed within the first channel and forming the first electrode; and
a second conductive material disposed within the second channel and forming the second electrode.

5. The photovoltaic device of claim 4, wherein at least one of the first and second conductive materials is a wire.

6. The photovoltaic device of claim 5, wherein the wire is maintained within the given channel via a conductive epoxy.

7. The photovoltaic device of claim 1, further comprising:
a substantially longitudinally oriented surface on which respective portions of the n-type region and the p-type regions of the core are exposed;
a first conductive layer of material disposed on the surface, electrically coupled with the n-type region and forming the first electrode; and
a second conductive layer of material disposed on the surface, electrically coupled with the p-type region and forming the second electrode.

8. The photovoltaic device of claim 7, wherein the substantially longitudinally oriented surface defines a substantially flat region surface characterizing the core and cladding in semi-circular cross-section, wherein a surface area of the semi-circular cross-section is greater than 50% of a full circular cross section thereof.

9. The photovoltaic device of claim 7, wherein the core is formed from one of n-type and p-type semiconductor material, and a cylindrically-shaped portion at an outer most periphery of the core is formed from the other of the n-type and p-type semiconductor material.

10. The photovoltaic device of claim 1, further comprising:
a semiconductor core including at least one p-n junction, defined by respective n-type and p-type regions;
a conductive wire disposed coaxially within the core and serving as a first electrode coupled to one of an n-type and p-type region;
a substantially transparent cladding in coaxial relationship with the semiconductor core, forming a longitudinally oriented cane; and
a second electrode electrically coupled to the other of the n-type and p-type regions of the core.

11. The photovoltaic device of claim 10, wherein the core is formed from one of n-type and p-type semiconductor material and is one of the n-type and p-type regions, and a cylindrically-shaped portion at an outer most periphery of the core is the other of the n-type and p-type regions.

12. The photovoltaic device of claim 10, further comprising:
a slot extending longitudinally along the cladding and extending from an outer surface of the cladding radially toward the core such that the slot communicates with at least one of the n-type and p-type regions of the core; and
a conductive material, serving as the second electrode, disposed in the slot and electrically coupled to the other of the n-type and p-type regions of the core.

13. The photovoltaic device of claim 1, further comprising:
a semiconductor core including at least one p-n junction, defined by respective n-type and p-type regions;
a first conductor disposed coaxially within the core and serving as a first electrode coupled to one of an n-type and p-type region;
a second conductor disposed coaxially within the core and serving as a second electrode coupled to the other of the n-type and p-type regions; and
a substantially transparent cladding in coaxial relationship with the semiconductor core.

14. The photovoltaic device of claim 13, wherein:
the core is formed from one of n-type and p-type semiconductor material and is one of the n-type and p-type regions; and
a cylindrically-shaped portion at an outer most periphery of the core is the other of the n-type and p-type regions.

15. The photovoltaic device of claim 14, further comprising first and second tubes, each surrounding a respective one of the first and second conductors, wherein the other of the n-type and p-type regions of the cylindrically-shaped portion surrounds the first and second tubes.

16. The photovoltaic device of claim 15, wherein the first and second tubes include respective longitudinally extending slots that extend through respective walls of the tubes such that the first and second conductors are in electrical communication with the respective n-type and p-type regions of the core.

17. An opto-electronic device, comprising:
at least a first core formed of a semiconductor material including at least one p-n junction, defined by respective n-type and p-type regions;
first and second electrodes, each being electrically coupled to a respective one of the n-type and p-type regions;
at least a second core formed of an optically transparent material having a first refractive index; and
a transparent cladding formed of glass, glass-ceramic, or polymer coaxially oriented about the cores, the cladding having a second refractive index,
wherein light propagating through the second core in a wave guiding mode interacts with the p-n junction of the first core.

18. The opto-electronic device, of claim 17, further comprising at least one longitudinally oriented void disposed among at least one of the first and second cores.

19. A photovoltaic device, comprising:
at least a first core formed of a first semiconductor material including at least one p-n junction, defined by respective n-type and p-type regions;
at least a second core formed of a second semiconductor material including at least one p-n junction, defined by respective n-type and p-type regions; and
a transparent cladding formed of glass, glass-ceramic, or polymer coaxially oriented about the cores,
wherein the first and second semiconductor cores are formed of different semiconductor types.

20. The photovoltaic device of claim 19, wherein the first and second cores are formed from semiconductor material taken from the group consisting of: GaAs, copper indium gallium diselenide, InP, SiGe, SiC, Ge, ZnO, ZnTe, and organic semiconductor material.

21. A photovoltaic device, comprising:
a transparent cane having a length and circular cross-section, formed of glass, glass-ceramic, or polymer;
at least one channel extending longitudinally along the length of the cane;
an n-type semiconductor plate disposed within the channel;
a p-type semiconductor plate disposed within the channel and in electrical communication with the n-type semiconductor plate defining at least one p-n junction;
a plug formed of the same material as the transparent cane filling a remainder of the channel; and
first and second electrodes, each being electrically coupled to a respective one of the n-type and p-type plates.

22. The photovoltaic device of claim 21, wherein the channel has a substantially V-shaped cross-section, the n-type and p-type semiconductor plates are disposed against opposite surfaces of the channel, and respective peripheral edges of the n-type and p-type semiconductor plates contact each other to form the at least one p-n junction.

23. The photovoltaic device of claim 21, wherein the channel has a substantially rectangular cross-section, the n-type and p-type semiconductor plates are disposed in an overlapping orientation, and respective major surfaces of the n-type and p-type semiconductor plates contact each other to form the at least one p-n junction.

24. A photovoltaic device, comprising:
a support structure; and
a plurality of photovoltaic cells coupled to the support structure, each cell being of substantially longitudinal extension and at least semi-circular cross-section, and each cell including:
a semiconductor core including at least one p-n junction, defined by respective n-type and p-type regions,
a substantially transparent cladding in coaxial relationship with the semiconductor core, forming a longitudinally oriented cane, and
first and second electrodes, each being electrically coupled to a respective one of the n-type and p-type regions,
wherein respective ones of the first and second electrodes of the photovoltaic cells are electrically coupled together to achieve an integrated source of voltage and current.

25. The photovoltaic device of claim 24, wherein the plurality of photovoltaic cells are disposed one next to the other such that the cladding of a given one of the cells is in close proximity, or touching, the cladding of an adjacent one of the cells.

26. The photovoltaic device of claim 24, wherein the substantially transparent cladding operates to focus solar rays toward the at least one p-n junction.

27. A method, comprising:
preparing a hollow blank suitable for use in a blank redraw process, the blank being formed from a material including at least one dopant operating to provide a source of dopant atoms for diffusing into another material;
introducing a semiconductor material into the hollow portion of the blank;
heating the blank and semiconductor material in a redraw furnace such that the blank and the semiconductor material flow; and
simultaneously drawing the blank and the semiconductor material such that: (i) a core formed by the semiconductor material is coaxially oriented within a cladding formed by the blank, and (ii) atoms from the at least one dopant diffuse into the semiconductor material of the core and form at least one p-n junction.

28. The method of claim 27, further comprising preparing the blank from a silica-based glass composition, wherein the dopants include at least one of boron, phosphorous, germanium, aluminum, and titanium.

29. The method of claim 28, wherein the semiconductor material of the core is formed from silicon, the at least one dopant includes boron for diffusing into the silicon to form a region of p-type silicon, the at least one dopant includes phosphorous for diffusing into the silicon to form a region of n-type silicon, and the p-type and n-type regions of silicon define the p-n junction.

30. The method of claim 28, wherein at least one of: the silica-based glass composition is a B2O3-GeO2-SiO2 composition, and the silica-based glass composition includes about 5-25% B2O3 and about 10-13% GeO2.

31. The method of claim 27, further comprising heat treating the drawn core with the cladding such that the one or more dopants further diffuse into the core.

32. The method of claim 27, further comprising:
preparing the blank from a material further including at least one slot on an exterior surface thereof, the slot extending lengthwise in a longitudinal direction of the blank and extending radially toward but not through to the hollow of the blank; and
simultaneously drawing the blank and the semiconductor material such that the slot extends radially toward the core.

33. The method of claim 32, further comprising:
at least one of etching and laser ablation of at least one channel within the slot such that the channel extends longitudinally along the slot of the cladding, and such that at least a portion thereof is adjacent to and in communication with at least one of the n-type and p-type regions of the core; and
disposing a conductive material within the at least one channel to form at least one of the first and second electrodes,
wherein the at least one channel and at least one of the first and second electrodes are located, sized and shaped such that voltage and current generated by the p-n junction is accessible outside the cladding.

34. The method of claim 33, further comprising:
at least one of etching and laser ablation of first and second channels within the slot such that each channel extends longitudinally along the slot of the cladding, and such that at least a portion of each channel is adjacent to and in communication with a respective one of the n-type and p-type regions of the core; and
disposing first and second conductive material within the respective first and second channels to form the respective first and second electrodes.

35. The method of claim 34, wherein at least one of the first and second conductive materials is a wire.

36. The method of claim 35, further comprising disposing conductive epoxy within at least one of the first and second channels such that the wire is maintained therein.

37. The method of claim 32, further comprising:
introducing a conductive wire into the hollow portion of the blank with the semiconductor material;
heating the blank, the semiconductor material, and the wire in the redraw furnace such that the blank and the semiconductor material flow; and
simultaneously drawing the blank, the semiconductor material, and the wire such that a core of the semiconductor material is coaxially oriented within a cladding produced from the hollow blank, and the wire is coaxially oriented within the core.

38. The method of claim 37, wherein the conductive wire is formed from one or more of aluminum, copper, refractory metals, tungsten, and molybdenum.

39. The method of claim 37, wherein the core is formed from one of n-type and p-type semiconductor material, thereby defining an n-type or p-type region, and the dopant from the blank diffuses into the core to form a cylindrically-shaped portion at an outer most periphery of the core, which is the other of the n-type or p-type region.

40. The method of claim 39, further comprising:
at least one of etching and laser ablation of the slot such that it communicates with one of the n-type and p-type regions of the core;
disposing a conductive material within the slot to form the second electrode,
wherein the at least one slot, the first electrode, and the second electrode are located, sized and shaped such that voltage and current generated by the p-n junction is accessible outside the cladding.

41. The method of claim 27, further comprising:
introducing at least one elongate tube into the hollow portion of the blank with the semiconductor material;
heating the blank, the semiconductor material, and the tube in the redraw furnace such that the blank and the semiconductor material flow; and
simultaneously drawing the blank, the semiconductor material, and the at least one tube such that a core of the semiconductor material is coaxially oriented within a cladding produced from the hollow blank, and the at least one tube is coaxially oriented within the core.

42. The method of claim 41, wherein the at least one tube is formed from a glass material and the method further comprises removing the at least one tube from within the core after the cane has been drawn via at least one of etching and laser ablation of the glass to produce at least one longitudinally extending aperture coaxially oriented within the core.

43. The method of claim 42, further comprising introducing a conductive material into the at least one aperture to serve as an electrode.

44. The method of claim 27, further comprising:
grinding or polishing a substantially longitudinally oriented surface into the cladding to expose respective portions of the n-type region and the p-type region of the core;
disposing a first conductive layer of material on the surface such that it is electrically coupled with the n-type region to form the first electrode; and
disposing a second conductive layer of material on the surface such that it is electrically coupled with the p-type region to form the second electrode.

45. The method of claim 44, wherein the substantially longitudinally oriented surface defines a substantially flat region surface characterizing the core and cladding in semi-circular cross-section, wherein a surface area of the semi-circular cross-section is greater than 50% of a full circular cross section thereof.

46. A method, comprising:
forming a channel extending longitudinally along a length of a blank of glass, glass-ceramic, or polymer, the blank being suitable for use in a blank redraw process;
disposing an n-type semiconductor plate within the channel;
disposing a p-type semiconductor plate within the channel in electrical communication with the n-type semiconductor plate to define at least one p-n junction;
disposing a plug formed of the same material as the blank at least partially within the channel to fill a remainder of the channel; and
heating the blank, semiconductor plates, and plug in a redraw furnace; and
simultaneously drawing the blank, semiconductor plates, and plug such that the semiconductor plates are disposed within a cane of generally circular cross-section.

47. The method of claim 46, further comprising:
removing some of the material of the cane to expose at least some portions of the semiconductor plates; and
disposing respective electrode material in electrical communication with each of the semiconductor plates such that voltage and current generated by the p-n junction is accessible outside the cane.

48. The method of claim 46, wherein the channel has a substantially V-shaped cross-section, the n-type and p-type semiconductor plates are disposed against opposite surfaces of the channel, and respective peripheral edges of the n-type and p-type semiconductor plates contact each other to form the at least one p-n junction.

49. The method of claim 46, wherein the channel has a substantially rectangular cross-section, the n-type and p-type semiconductor plates are disposed in an overlapping orientation, and respective major surfaces of the n-type and p-type semiconductor plates contact each other to form the at least one p-n junction.
